(19) United States
(12) Patent Application Publication
(10) Pub. No.: US 2019/0136368 A1
(43) Pub. Date: May 9, 2019

(54) SPUTTERING APPARATUS AND METHOD OF MANUFACTURING MAGNETIC MEMORY DEVICE USING THE SAME

(71) Applicant: SAMSUNG ELECTRONICS CO., LTD., Suwon-si (KR)

(72) Inventors: Ki Woong KIM, Hwaseong-si (KR); Woojin KIM, Yongin-si (KR); Sang Hwan PARK, Hwaseong-si (KR); Heeju SHIN, Seoul (KR); Se Chung OH, Yongin-si (KR)

(73) Assignee: SAMSUNG ELECTRONICS CO., LTD., Suwon-si (KR)

(21) Appl. No.: 15/980,348

(22) Filed: May 15, 2018

(30) Foreign Application Priority Data
Nov. 6, 2017 (KR) 10-2017-0146816

(51) Int. Cl. C23C 14/35; H01L 43/10; H01L 43/12; C23C 14/34; H01J 37/34

(52) U.S. Cl. CPC C23C 14/352; H01L 43/10; H01J 37/3405; C23C 14/3407; H01L 43/12

(57) ABSTRACT

Provided are sputtering apparatuses and methods of manufacturing magnetic memory devices. The sputtering apparatus includes a process chamber, a stage in the process chamber and configured to load a substrate thereon, and a first sputter gun above the substrate in the process chamber. The first sputter gun is horizontally spaced apart from the substrate. The first sputter gun includes a first target including a first end and a second end, the first end being horizontally closer to the substrate than the second end. A first surface of the first target is inclined relative to a top surface of the substrate. A height of the second end of the first target relative to the top surface of the substrate is greater than that of the first end of the first target.

### CROSS-REFERENCE TO RELATED APPLICATION

This U.S. nonprovisional patent application claims priority under 35 U.S.C § 119 from Korean Patent Application No. 10-2017-0146816, filed on Nov. 6, 2017 in the Korean Intellectual Property Office (KIPO), the entire contents of which are hereby incorporated by reference.

### BACKGROUND

Apparatuses and methods consistent with one or more exemplary embodiments relate to a sputtering apparatus for thin-film deposition and a method of manufacturing a magnetic memory device using the same.

As electronic products trend toward high speed and/or low power consumption, high speed and low operating voltage are increasingly required for semiconductor memory devices incorporated in the electronic products. Accordingly, magnetic memory devices have been developed as semiconductor memory devices. Since magnetic memory devices may operate at high speed and have nonvolatile characteristics, they have attracted considerable attention as the next-generation semiconductor memory devices.

In general, the magnetic memory device may include a magnetic tunnel junction (MTJ) pattern. The magnetic tunnel junction pattern may include two magnetic structures and an insulation layer interposed therebetween. The resistance of the magnetic tunnel junction pattern may vary depending on magnetization directions of the two magnetic structures. For example, the magnetic tunnel junction pattern may have high resistance when the magnetization directions of the two magnetic structures are not parallel and low resistance when the magnetization directions of the two magnetic structures are parallel. The magnetic memory device may write and/or read data using the resistance difference between the high and low resistances of the magnetic tunnel junction pattern. A sputtering process may be used to deposit the insulation layer of the magnetic tunnel junction pattern.

### SUMMARY

Aspects of one or more exemplary embodiments provide a sputtering apparatus capable of minimizing contamination of a substrate provided therein.

Aspects of one or more exemplary embodiments also provide a sputtering apparatus capable of reducing deterioration of characteristics of thin films.

Aspects of one or more exemplary embodiments also provide a method of manufacturing a magnetic memory device with improved electrical characteristics.

According to an aspect of an exemplary embodiment, there is provided a sputtering apparatus, including: a process chamber; a stage in the process chamber and configured to load a substrate thereon; and a first sputter gun above the substrate in the process chamber, wherein the first sputter gun is horizontally spaced apart from the substrate, wherein the first sputter gun includes a first target including a first end and a second end, the first end being horizontally closer to the substrate than the second end, and wherein a first surface of the first target is inclined relative to a top surface of the substrate, and a height of the second end of the first target relative to the top surface of the substrate is greater than a height of the first end of the first target relative to the top surface of the substrate.

According to an aspect of another exemplar embodiment, there is provided a sputtering apparatus, including: a process chamber; a stage in the process chamber and configured to load a substrate thereon; a first sputter gun above the substrate in the process chamber, the first sputter gun including a first target; and a second sputter gun above the substrate in the process chamber, the second sputter gun including a second target, wherein the first sputter gun and the second sputter gun are horizontally spaced apart from the substrate, wherein the first target comprises a first end and a second end, the first end being horizontally closer to the substrate than the second end, and wherein a first surface of the first target is inclined relative to a top surface of the substrate, and a height of the second end of the first target relative to the top surface of the substrate is greater than a height of the first end of the first target relative to the top surface of the substrate.

According to an aspect of another exemplar embodiment, there is provided a method of manufacturing a magnetic memory device, the method including: sequentially forming a first magnetic layer, a non-magnetic layer, and a second magnetic layer on a substrate, wherein the sequentially forming includes: forming the non-magnetic layer by performing a sputtering process using a first sputter gun above the substrate, wherein the first sputter gun is horizontally spaced apart from the substrate, wherein the first sputter gun includes a first target including a first end and a second end, the first end being horizontally closer to the substrate than the second end, and wherein a first surface of the first target is inclined relative to a top surface of the substrate, and a height of the second end of the first target relative to the top surface of the substrate is greater than a height of the first end of the first target relative to the top surface of the substrate.

According to an aspect of another exemplary embodiment, there is provided a sputtering apparatus, including: a process chamber; a stage in the process chamber and configured to load a substrate thereon; and a first sputter gun above the substrate in the process chamber and including a first target, wherein the first sputter gun is horizontally spaced apart from the substrate, wherein a first projection area of the first sputter gun is horizontally spaced apart from a top surface of the substrate, the first projection area being an area formed when a first surface of the first target extends along a first normal line onto a plane including the top surface of the substrate, the first normal line being perpendicular to the first surface of the first target.

### BRIEF DESCRIPTION OF THE DRAWINGS

These and/or other aspects of the disclosure will become apparent and more readily appreciated from the following description of exemplary embodiments, taken in conjunction with the accompanying drawings of which:

FIG. 1 is a plan view illustrating a sputtering apparatus according to an exemplary embodiment;

FIG. 2 is a cross-sectional view taken along line I-I′ of FIG. 1, illustrating a sputtering apparatus according to an exemplary embodiment;

FIG. 3 is a cross-sectional view taken along line I-I′ of FIG. 1, illustrating a sputtering apparatus according to an exemplary embodiment;

FIG. 4 is a cross-sectional view taken along line I-I′ of FIG. 1, illustrating a sputtering apparatus according to an exemplary embodiment;

FIG. 5 is a cross-sectional view taken along line I-I′ of FIG. 1, illustrating a sputtering apparatus according to an exemplary embodiment;

FIG. 6 is a flowchart illustrating a method of manufacturing a magnetic memory device according to an exemplary embodiment;

FIGS. 7 to 10 are cross-sectional views illustrating a method of manufacturing a magnetic memory device according to one or more exemplary embodiments;

FIG. 11 is a cross-sectional view illustrating an example of a magnetic tunnel junction pattern fabricated according to an exemplary embodiment;

FIG. 12 is a cross-sectional view illustrating an example of a magnetic tunnel junction pattern fabricated according to an exemplary embodiment; and

FIG. 13 is a circuit diagram illustrating a unit memory cell of a magnetic memory device according to an exemplary embodiment.

### DETAILED DESCRIPTION OF EXEMPLARY EMBODIMENTS

Hereinafter, one or more exemplary embodiments will be described in detail in conjunction with the accompanying drawings, wherein like reference numerals refer to like elements throughout. As used herein, the term “and/or” includes any and all combinations of one or more of the associated listed items. Similarly, expressions such as “at least one of,” when preceding a list of elements, modify the entire list of elements and do not modify the individual elements of the list.

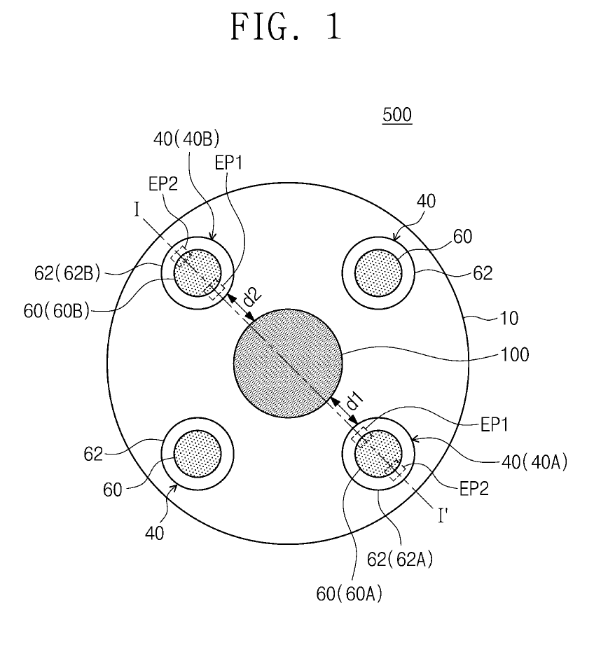

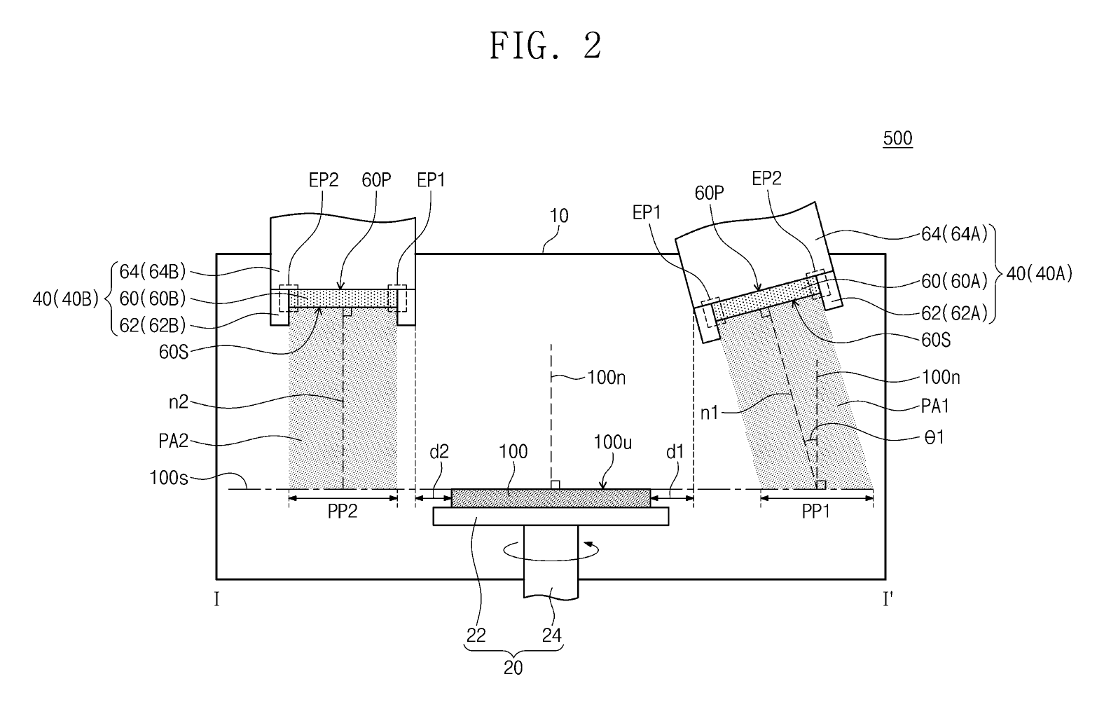

FIG. 1 is a plan view illustrating a sputtering apparatus 500 according to an exemplary embodiment. FIG. 2 is a cross-sectional view taken along line I-I′ of FIG. 1, illustrating a sputtering apparatus 500 according to an exemplary embodiment.

Referring to FIGS. 1 and 2, a sputtering apparatus 500 may include a process chamber 10 in which a sputtering process is performed. The process chamber 10 may be a vacuum chamber, and the sputtering process may be a sputtering deposition process for deposition of thin films. The sputtering apparatus 500 may include a substrate holder 20 provided in the process chamber 10 and a plurality of sputter guns 40 provided above a substrate 100 loaded on the substrate holder 20. The substrate holder 20 may include a stage 22 on which the substrate 100 is placed and a supporter 24 by which the stage 22 is supported. The supporter 24 may be configured to rotate the stage 22. The supporter 24 may turn the stage 22 when the sputtering process is performed, and therefore the substrate 100 may rotate during the sputtering process.

The plurality of sputter guns 40 may be perpendicularly spaced apart from the substrate 100, and may be horizontally spaced apart from each other. Each of the plurality of sputter guns 40 may be provided to be spaced apart from the substrate 100, when viewed in a plan as in FIG. 1 (i.e., horizontally spaced apart). Though four sputter guns 40 are illustrated in FIG. 1, it is understood that one or more other exemplary embodiments are not limited thereto. For example, at least two sputter guns 40 may be provided in the process chamber 10. Each of the plurality of sputter guns 40 may include a target 60, a shield 62 surrounding a periphery of the target 60 while exposing one surface (e.g., first surface) of the target 60, and a plate 64 supplying the target 60 with power. The target 60 may have an opposite surface (e.g., second surface), opposite to the one surface, on which the plate 64 is provided.

Among the plurality of sputter guns 40, a first sputter gun 40A may include a first target 60A, a first shield 62A surrounding a periphery of the first target 60A while exposing one surface 60S (e.g., first surface) of the first target 60A, and a first plate 64A provided on an opposite surface 60P (e.g., second surface) of the first target 60A and supplying the first target 60A with power. The opposite surface 60P of the first target 60A may be on an opposing side, relative to the one surface 60S, of the first target 60A. The first sputter gun 40A may be spaced apart from the substrate 100 by a first distance d1, when viewed in a plan as in FIG. 1. When viewed in a plan, the first sputter gun 40A may be provided such that the first shield 62A is horizontally spaced apart from the substrate 100 by the first distance d1.

The first sputter gun 40A may be disposed such that the one surface 60S of the first target 60A is non-perpendicular to a top surface 100U of the substrate 100. The first target 60A may include a first end EP1 adjacent to the substrate 100 and a second end EP2 more distant from the substrate 100 as compared to the first end EP1, when viewed in a plan. The first sputter gun 40A may be disposed such that the one surface 60S of the first target 60A is inclined relative to the top surface 100U of the substrate 100. Additionally, when viewed in a cross-section as in FIG. 2, the second end EP2 of the first target 60A may be located at a greater height (i.e., vertical height) relative to the top surface 100U of the substrate 100 than that of the first end EP1 of the first target 60A. A first angle θ1 may be formed between a first normal line n1 perpendicular to and extending vertically from the one surface 60S of the first target 60A and a reference normal line 100n perpendicular to and extending vertically from the top surface 100U of the substrate 100. The first angle θ1 may range from about 1° to about 50°. For example, the first angle θ1 may range from about 1° to about 5°.

The first sputter gun 40A may have a first projection area PA1. The first projection area PA1 may refer to an area created when the one surface 60S of the first target 60A extends or projects along a direction perpendicular to the one surface 60S of the first target 60A (or along the first normal line n1) onto a plane 100s including the top surface 100U of the substrate 100. Sputtering sources generated from the one surface 60S of the first target 60A may be distributed in the first projection area PA1. The first sputter gun 40A may be disposed such that the first projection area PA1 is horizontally spaced apart from the top surface 100U of the substrate 100. The first sputter gun 40A may be inclined relative to the top surface 100U of the substrate 100 such that a projected plane PP1 (e.g., first projected plane) of the first projection area PA1 is distant from the substrate 100. In this description, the projected plane PP1 of the first projection area PA1 may refer to a plane formed when the one surface 60S of the first target 60A is projected along the first normal line n1 onto the plane 100s.

Among the plurality of sputter guns 40, a second sputter gun 40B may include a second target 60B, a second shield 62B surrounding a periphery of the second target 60B while exposing one surface 60S (e.g., first surface) of the second target 60B, and a second plate 64B provided on an opposite surface 60P (e.g., second surface) of the second target 60B and supplying the second target 60B with power. The opposite surface 60P of the second target 60B may be on an opposing side, relative to the one surface 60S, of the second target 60B. The second sputter gun 40B may be spaced apart from the substrate 100 by a second distance d2, when viewed in a plan as in FIG. 1. The second distance d2 may be identical to or different from the first distance d1. When viewed in a plan, the second sputter gun 40B may be provided such that the second shield 62B is horizontally spaced apart from the substrate 100 by the second distance d2. The first sputter gun 40A and the second sputter gun 40B may be arranged to face each other, but it is understood that one or more other exemplary embodiments are not limited thereto.

The second sputter gun 40B may be disposed such that the one surface 60S of the second target 60B is non-perpendicular to the top surface 100U of the substrate 100. The second target 60B may include a first end EP1 adjacent to the substrate 100 and a second end EP2 more distant from the substrate 100 as compared to the first end EP1, when viewed in a plan as in FIG. 1. The second sputter gun 40B may be disposed such that the one surface 60S of the second target 60B is parallel to the top surface 100U of the substrate 100. In this case, the first end EP1 and the second end EP2 of the second target 60B may be located at substantially the same height relative to the top surface 100U of the substrate 100. A second normal line n2 perpendicular to the one surface 60S of the second target 60B may be parallel to the reference normal line 100n. The first sputter gun 40A and the second sputter gun 40B may be provided asymmetrically about the reference normal line 100n, when viewed in a cross-section as in FIG. 2.

The second sputter gun 40B may have a second projection area PA2. The second projection area PA2 may refer to an area created when the one surface 60S of the second target 60B extends or projects along a direction perpendicular to the one surface 60S of the second target 60B (or along the second normal line n2) onto the plane 100s including the top surface 100U of the substrate 100. Sputtering sources generated from the one surface 60S of the second target 60B may be distributed in the second projection area PA2. The second sputter gun 40B may be disposed such that the second projection area PA2 is horizontally spaced apart from the top surface 100U of the substrate 100. A projected plane PP2 of the second projection area PA2 may be closer to the substrate 100 than the projected plane PP1 of the first projection area PA1. In this description, the projected plane PP2 of the second projection area PA2 may refer to a plane formed when the one surface 60S of the second target 60B is projected along the second normal line n2 onto the plane 100s.

The first target 60A and the second target 60B may include the same material as each other. For example, the first target 60A and the second target 60B may include metal oxide such as magnesium (Mg) oxide, titanium (Ti) oxide, aluminum (Al) oxide, potassium (Ca) oxide, zirconium (Zr) oxide, magnesium-zinc (Mg—Zn) oxide, or magnesium-boron (Mg—B) oxide. Among the plurality of sputter guns 40, other sputter guns 40 may include corresponding targets 60 having the same material as those of the first target 60A and the second target 60B. Each of the other sputter guns 40 may be configured identically or similarly to the first sputter gun 40A or the second sputter gun 40B. It is understood that in one or more other exemplary embodiments, the other sputter guns 40 may not be provided.

When the sputtering process is performed in the process chamber 10, the targets 60 of the plurality of sputter guns 40 may be sputtered by plasma generated using a source gas (e.g., Argon (Ar) gas) supplied into the process chamber 10. Some of sputtering sources generated from the targets 60 may be deposited on the substrate 100, which may form a thin film on the substrate 100. Others of sputtering sources generated from the targets 60 may be deposited on outer surfaces of the plurality of sputter guns 40, which may produce a particle source. The particle source may be peeled off from the outer surfaces of the plurality of sputter guns 40 during or after the sputtering process, and may then fall onto the substrate 100. The peeled-off particle source may lead to contamination of the substrate 100.

According to aspects of one or more exemplary embodiments, when viewed in a plan, each of the plurality of sputter guns 40 may be provided spaced apart from the substrate 100 (i.e., horizontally spaced apart from the substrate 100). Accordingly, even though the particle source is peeled off from the outer surfaces of the plurality of sputter guns 40, the peeled-off particle source that falls onto the substrate 100 may be minimized or prevented. As a result, contamination of the substrate 100 caused by the peeled-off particle source may be minimized or prevented.

When the target 60 includes metal oxide, oxygen ions (or radicals) of sputtering sources generated from the target 60 may be concentrically distributed on the center of a projection area of the sputter gun 40 including the target 60. The projection area may refer to an area created when one surface of the target 60 extends or projects along a direction perpendicular to the one surface of the target 60 onto the plane 100s including the top surface 100U of the substrate 100. For example, the sputtering sources may be irregularly distributed in the projection area. If the projection area overlaps with the top surface 100U of the substrate 100, an irregular distribution of the sputtering sources may deteriorate characteristics of thin films formed when the sputtering sources are deposited on the substrate 100.

According to aspects of one or more exemplary embodiments, the first sputter gun 40A and the second sputter gun 40B may be disposed such that the first projection area PA1 and the second projection area PA2 are horizontally spaced apart from the top surface 100U of the substrate 100. In this case, some of sputtering sources generated from the first target 60A and the second target 60B may diffuse toward the substrate 100 from the first projection area PA1 and the second projection area PA2, and the diffused sputtering sources may be deposited to form a thin film on the substrate 100. The thin film formed by the diffused sputtering sources may be less affected by an irregular distribution of the sputtering sources in the first projection area PA1 and the second projection area PA2. Accordingly, deterioration in characteristics of the thin film may be decreased.

In addition, the first sputter gun 40A may be inclined relative to the top surface 100U of the substrate 100 such that the projected plane PP1 (e.g., first projected plane) of the first projection area PA1 is distant from the substrate 100. In this case, the irregular distribution of the sputtering sources in the first projection area PA1 may have less of an effect on characteristics of the thin film, but a deposition rate of the thin film may decrease. The second sputter gun 40B may be disposed such that the projection plane PP2 (e.g., second projected plane) of the second projection area PA2 is closer to the substrate 100 than the projected plane PP1 of the first projection area PA1. Accordingly, the reduction in deposition rate of the thin film may be compensated.

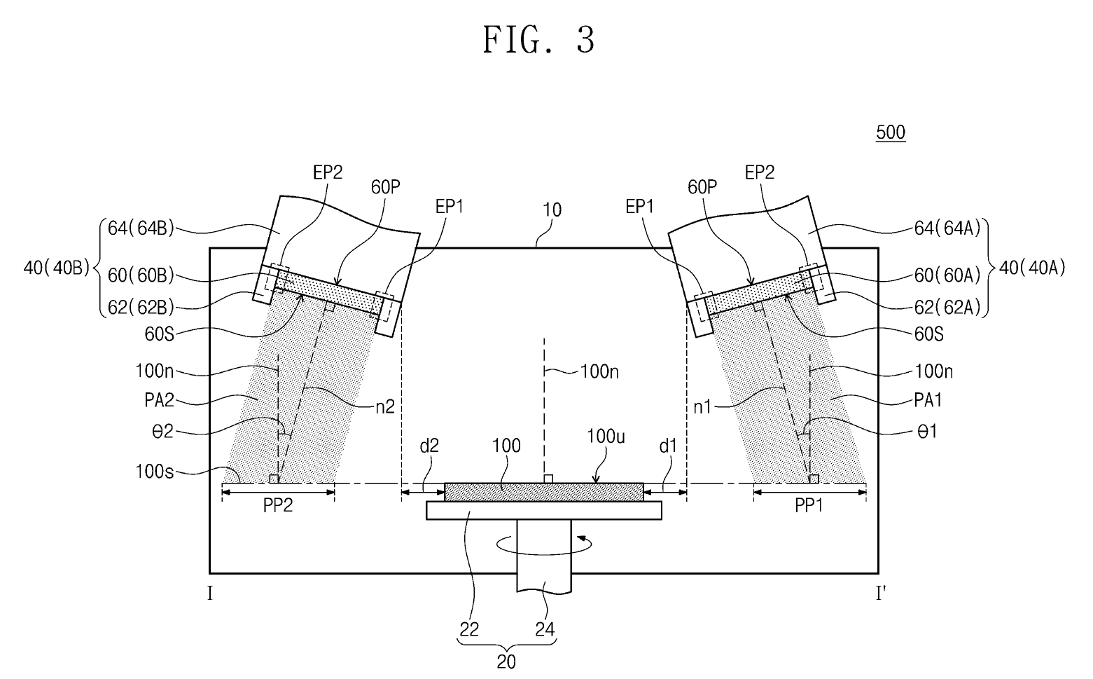

FIG. 3 is a cross-sectional view taken along line I-I′ of FIG. 1, illustrating a sputtering apparatus 500 according to an exemplary embodiment.

Referring to FIGS. 1 and 3, among the plurality of sputter guns 40, a second sputter gun 40B may include a second target 60B, a second shield 62B surrounding a periphery of the second target 60B while exposing one surface 60S (e.g., first surface) of the second target 60B, and a second plate 64B provided on an opposite surface 60P (e.g., second surface) of the second target 60B and supplying the second target 60B with power. The second sputter gun 40B may be spaced apart from the substrate 100 by a second distance d2, when viewed in a plan as in FIG. 1. The second distance d2 may be the same as the first distance d1, though it is understood that one or more other exemplary embodiments are not limited thereto. When viewed in a plan, the second sputter gun 40B may be provided such that the second shield 62B is horizontally spaced apart from the substrate 100 by the second distance d2. The first sputter gun 40A and the second sputter gun 40B may be arranged to face each other, though it is understood that one or more other exemplary embodiments are not limited thereto.

The second sputter gun 40B may be disposed such that the one surface 60S of the second target 60B is non-perpendicular to the top surface 100U of the substrate 100. The second target 60B may include a first end EP1 adjacent to the substrate 100 and a second end EP2 distant from the substrate 100, when viewed in a plan as in FIG. 1. The second sputter gun 40B may be disposed such that the one surface 60S of the second target 60B is inclined relative to the top surface 100U of the substrate 100. Additionally, when viewed in a cross-section as in FIG. 3, the second end EP2 of the second target 60B may be located at a greater height relative to the top surface 100U of the substrate 100 than that of the first end EP1 of the second target 60B. A second angle θ2 may be formed between a second normal line n2 perpendicular to the one surface 60S of the second target 60B and the reference normal line 100n perpendicular to the top surface 100U of the substrate 100. The second angle θ2 may range from about 1° to about 50°. For example, the second angle θ2 may range from about 1° to about 5°. The second angle θ2 may be the same as the first angle θ1, though it is understood that one or more other exemplary embodiments are not limited thereto. The first sputter gun 40A and the second sputter gun 40B may be provided symmetrically about the reference normal line 100n, when viewed in a cross-section.

The second sputter gun 40B may have a second projection area PA2. The second projection area PA2 may refer to an area created when the one surface 60S of the second target 60B extends or projects along a direction perpendicular to the one surface 60S of the second target 60B (or along the second normal line n2) onto the plane 100s including the top surface 100U of the substrate 100. Sputtering sources generated from the one surface 60S of the second target 60B may be distributed in the second projection area PA2. The second sputter gun 40B may be disposed such that the second projection area PA2 is horizontally spaced apart from the top surface 100U of the substrate 100. The second sputter gun 40B may be inclined relative to the top surface 100U of the substrate 100 such that a projected plane PP2 of the second projection area PA2 is distant from the substrate 100. In this description, the projected plane PP2 of the second projection area PA2 may be a plane formed when the one surface 60S of the second target 60B is projected along the second normal line n2 onto the plane 100s.

The sputtering apparatus 500 according to the present exemplary embodiment may be substantially the same as the sputtering apparatus 500 discussed with reference to FIGS. 1 and 2, other than the above-described second sputter gun 40B.

According to the present exemplary embodiment, the first sputter gun 40A may be inclined relative to the top surface 100U of the substrate 100 such that the projected plane PP1 of the first projection area PA1 is distant from the substrate 100, and the second sputter gun 40B may be inclined relative to the top surface 100U of the substrate 100 such that the projected plane PP2 of the second projection area PA2 is distant from the substrate 100. For example, when viewed in a cross-section as in FIG. 3, the first sputter gun 40A and the second sputter gun 40B may be provided symmetrically about the reference normal line 100n. In this case, the thin film may be less affected by the irregular distribution of the sputtering sources in the first projection area PA1 and the second projection area PA2. Accordingly, deterioration in characteristics of the thin film may be minimized.

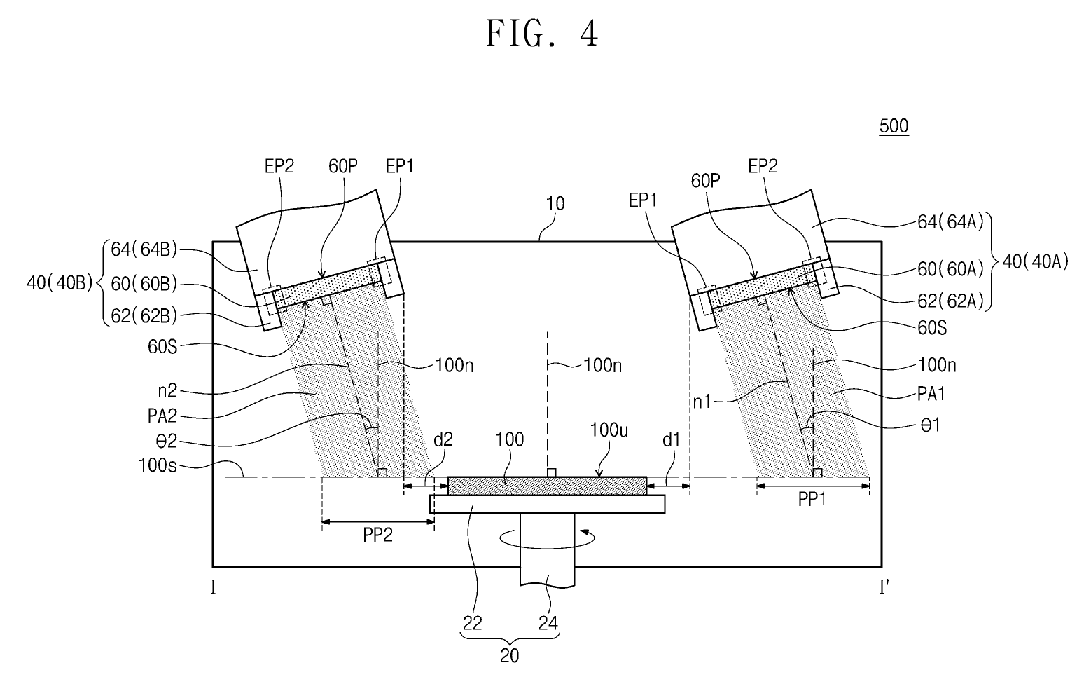

FIG. 4 is a cross-sectional view taken along line I-I′ of FIG. 1, illustrating a sputtering apparatus 500 according to an exemplary embodiment.

Referring to FIGS. 1 and 4, among the plurality of sputter guns 40, a second sputter gun 40B may include a second target 60B, a second shield 62B surrounding a periphery of the second target 60B while exposing one surface 60S (e.g., first surface) of the second target 60B, and a second plate 64B provided on an opposite surface 60P (e.g., second surface) of the second target 60B and supplying the second target 60B with power. The second sputter gun 40B may be spaced apart from the substrate 100 by a second distance d2, when viewed in a plan as in FIG. 1. The second distance d2 may be greater than the first distance d1, though it is understood that one or more other exemplary embodiments are not limited thereto. When viewed in a plan, the second sputter gun 40B may be provided such that the second shield 62B is horizontally spaced apart from the substrate 100 by the second distance d2. The first sputter gun 40A and the second sputter gun 40B may be arranged to face each other, though it is understood that one or more other exemplary embodiments are not limited thereto.

The second sputter gun 40B may be disposed such that the one surface 60S of the second target 60B is non-perpendicular to the top surface 100U of the substrate 100. The second target 60B may include a first end EP1 adjacent to the substrate 100 and a second end EP2 distant from the substrate 100, when viewed in a plan. The second sputter gun 40B may be disposed such that the one surface 60S of the second target 60B is inclined relative to the top surface 100U of the substrate 100. Additionally, when viewed in a cross-section as in FIG. 4, the first end EP1 of the second target 60B may be located at a greater height relative to the top surface 100U of the substrate 100 than that of the second end EP2 of the second target 60B. A second angle θ2 may be formed between a second normal line n2 perpendicular to the one surface 60S of the second target 60B and the reference normal line 100n perpendicular to the top surface 100U of the substrate 100. The second angle θ2 may range from about 1° to about 50°. For example, the second angle θ2 may range from about 1° to about 5°. The second angle θ2 may be greater than the first angle θ1, though it is understood that one or more other exemplary embodiments are not limited thereto. The first sputter gun 40A and the second sputter gun 40B may be provided asymmetrically about the reference normal line 100n, when viewed in a cross-section.

The second sputter gun 40B may have a second projection area PA2. The second projection area PA2 may refer to an area created when the one surface 60S of the second target 60B extends or projects along a direction perpendicular to the one surface 60S of the second target 60B (or along the second normal line n2) onto the plane 100s including the top surface 100U of the substrate 100. Sputtering sources generated from the one surface 60S of the second target 60B may be distributed in the second projection area PA2. The second sputter gun 40B may be disposed such that the second projection area PA2 is horizontally spaced apart from the top surface 100U of the substrate 100. The second sputter gun 40B may be inclined relative to the top surface 100U of the substrate 100 such that a projected plane PP2 of the second projection area PA2 is close to the substrate 100. In this description, the projected plane PP2 of the second projection area PA2 may refer to a plane formed when the one surface 60S of the second target 60B is projected along the second normal line n2 onto the plane 100s. The projected plane PP2 of the second projection area PA2 may be closer to the substrate 100 than the projected plane PP1 of the first projection area PA1.

The sputtering apparatus 500 according to the present exemplary embodiment may be substantially the same as the sputtering apparatus 500 discussed with reference to FIGS. 1 and 2, other than the above-described second sputter gun 40B.

According to the present exemplary embodiment, the first sputter gun 40A may be inclined relative to the top surface 100U of the substrate 100 such that the projected plane PP1 of the first projection area PA1 is distant from the substrate 100. The second sputter gun 40B may be inclined relative to the top surface 100U of the substrate 100 such that the projected plane PP2 of the second projection area PA2 is close to the substrate 100. For example, when viewed in a cross-section as in FIG. 4, the first sputter gun 40A and the second sputter gun 40B may be provided asymmetrically about the reference normal line 100n. In this case, the characteristics of the thin film may be less affected by the irregular distribution of the sputtering sources in the first projection area PA1, though a deposition rate of the thin film may decrease. The second sputter gun 40B may be disposed such that the projection plane PP2 of the second projection area PA2 is closer to the substrate 100 than the projected plane PP1 of the first projection area PA1. Accordingly, the reduction in deposition rate of the thin film may be compensated.

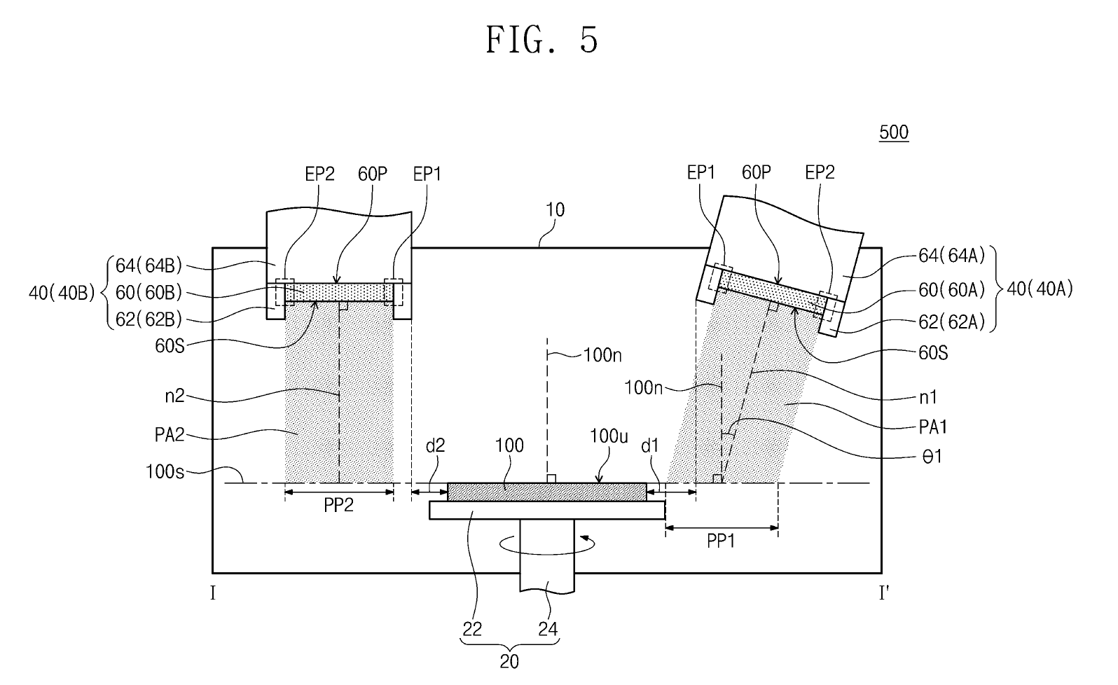

FIG. 5 is a cross-sectional view taken along line I-I′ of FIG. 1, illustrating a sputtering apparatus 500 according to an exemplary embodiment.

Referring to FIGS. 1 and 5, among the plurality of sputter guns 40, a first sputter gun 40A may include a first target 60A, a first shield 62A surrounding a periphery of the first target 60A while exposing one surface 60S (e.g., first surface) of the first target 60A, and a first plate 64A provided on an opposite surface 60P (e.g., second surface) of the first target 60A and supplying the first target 60A with power. The first sputter gun 40A may be spaced apart from the substrate 100 by a first distance d1, when viewed in a plan as in FIG. 1. When viewed in a plan, the first sputter gun 40A may be provided such that the first shield 62A is horizontally spaced apart from the substrate 100 by the first distance d1.

The first sputter gun 40A may be disposed such that the one surface 60S of the first target 60A is non-perpendicular to the top surface 100U of the substrate 100. The first target 60A may include a first end EP1 adjacent to the substrate 100 and a second end EP2 distant from the substrate 100, when viewed in a plan as in FIG. 1. The first sputter gun 40A may be disposed such that the one surface 60S of the first target 60A is inclined relative to the top surface 100U of the substrate 100. Additionally, when viewed in a cross-section as in FIG. 5, the first end EP1 of the first target 60A may be located at a greater height relative to the top surface 100U of the substrate 100 than that of the second end EP2 of the first target 60A. A first angle θ1 may be formed between a first normal line n1 perpendicular to the one surface 60S of the first target 60A and the reference normal line 100n perpendicular to the top surface 100U of the substrate 100. The first angle θ1 may range from about 1° to about 50°. For example, the first angle θ1 may range from about 1° to about 5°.

The first sputter gun 40A may have a first projection area PA1. The first projection area PA1 may refer to an area created when the one surface 60S of the first target 60A extends or projects along a direction perpendicular to the one surface 60S of the first target 60A (or along the first normal line n1) onto the plane 100s including the top surface 100U of the substrate 100. Sputtering sources generated from the one surface 60S of the first target 60A may be distributed in the first projection area PA1. The first sputter gun 40A may be disposed such that the first projection area PA1 is horizontally spaced apart from the top surface 100U of the substrate 100. The first sputter gun 40A may be inclined relative to the top surface 100U of the substrate 100 such that a projected plane PP1 of the first projection area PA1 is close to the substrate 100. In this description, the projected plane PP1 of the first projection area PA1 may refer to a plane formed when the one surface 60S of the first target 60A is projected along the first normal line n1 onto the plane 100s.

Among the plurality of sputter guns 40, a second sputter gun 40B may be substantially the same as the second sputter gun 40B discussed with reference to FIGS. 1 and 2. The second sputter gun 40B may be spaced apart from the substrate 100 by the second distance d2, when viewed in a plan. The first distance d1 may be greater than the second distance d2, though it is understood that one or more other exemplary embodiments are not limited thereto. The second sputter gun 40B may be disposed such that the one surface 60S of the second target 60B is parallel to the top surface 100U of the substrate 100. The second normal line n2 perpendicular to the one surface 60S of the second target 60B may be parallel to the reference normal line 100n. The first sputter gun 40A and the second sputter gun 40B may be provided asymmetrically about the reference normal line 100n, when viewed in a cross-section as in FIG. 5.

The second sputter gun 40B may be disposed such that the second projection area PA2 is horizontally spaced apart from the top surface 100U of the substrate 100. The projected plane PP1 of the first projection area PA1 may be closer to the substrate 100 than the projected plane PP2 of the second projection area PA2.

The sputtering apparatus 500 according to the present exemplary embodiment may be substantially the same as the sputtering apparatus 500 discussed with reference to FIGS. 1 and 2, other than the features described above.

According to the present exemplary embodiment, the first sputter gun 40A and the second sputter gun 40B may be disposed such that the first projection area PA1 and the second projection area PA2 are horizontally spaced apart from the top surface 100U of the substrate 100. In this case, characteristics of the thin film may be less affected by the irregular distribution of the sputtering sources in the first projection area PA1 and the second projection area PA2, and therefore deterioration in characteristics of the thin film may decrease.

The sputtering apparatus 500 may be used to manufacture a magnetic memory device. A method of manufacturing a magnetic memory device will be discussed below.

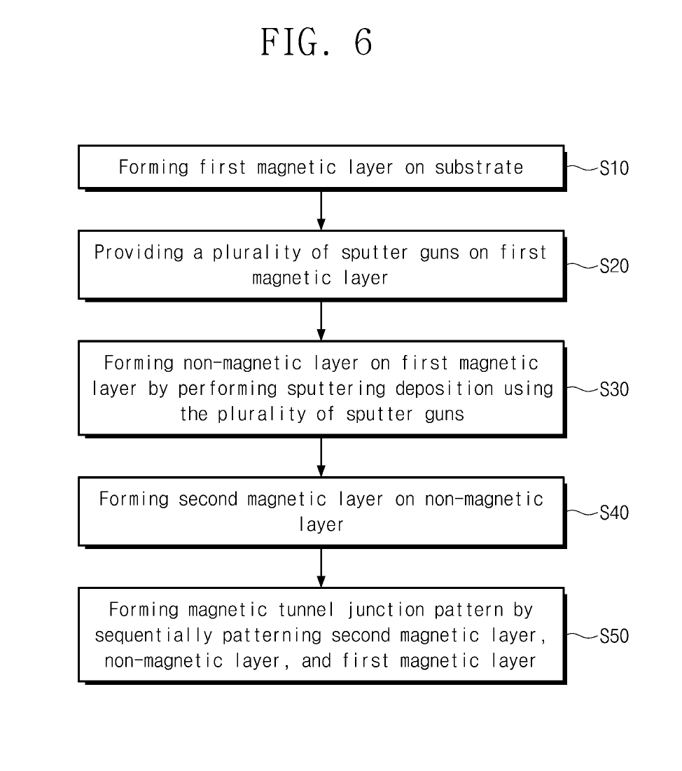

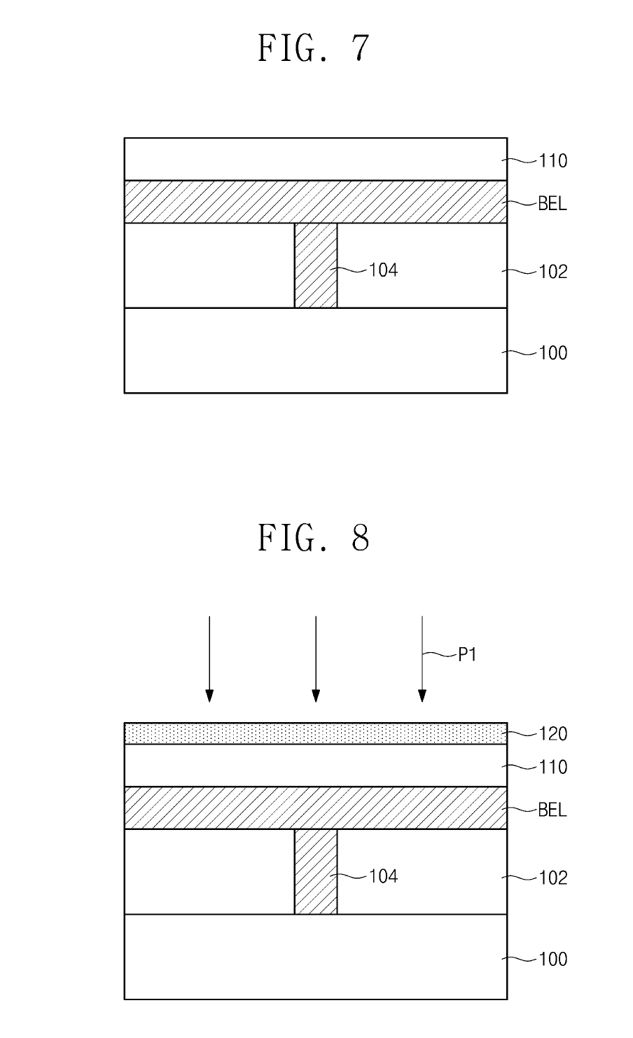

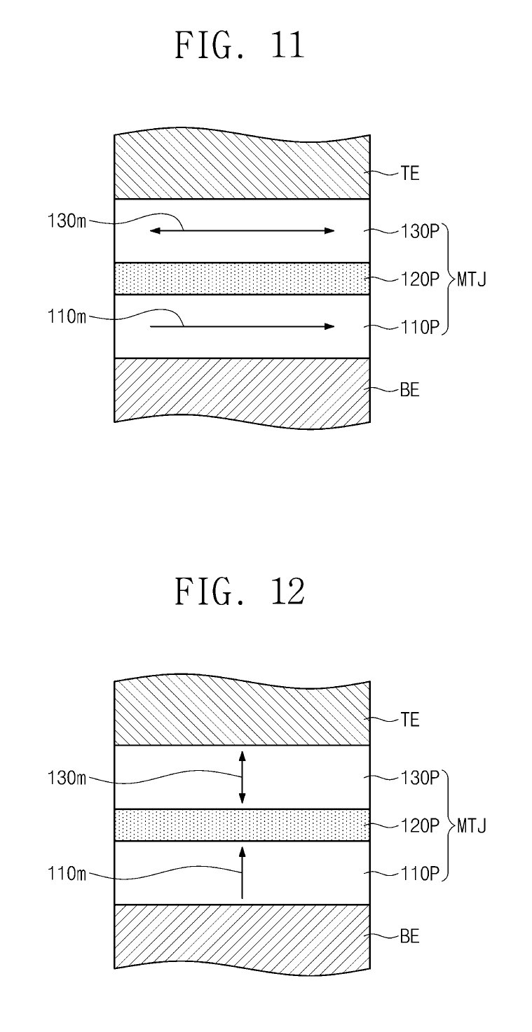

FIG. 6 is a flowchart illustrating a method of manufacturing a magnetic memory device according to an exemplary embodiment. FIGS. 7 to 10 are cross-sectional views illustrating a method of manufacturing a magnetic memory device according to one or more exemplary embodiments. FIG. 11 is a cross-sectional view illustrating an example of a magnetic tunnel junction pattern fabricated according to an exemplary embodiment. FIG. 12 is a cross-sectional view illustrating an example of a magnetic tunnel junction pattern fabricated according to an exemplary embodiment.

Referring to FIGS. 6 and 7, a lower interlayer dielectric layer 102 may be formed on a substrate 100. The substrate 100 may include a semiconductor substrate. For example, the substrate 100 may include a silicon substrate, a germanium substrate, or a silicon-germanium substrate. In one or more exemplary embodiments, select elements may be formed on the substrate 100, and the lower interlayer dielectric layer 102 may formed to cover the select elements. The select elements may be or may include field effect transistors. Alternatively, the select elements may be or may include diodes. The lower interlayer dielectric layer 102 may be formed as a single layer or multiple layers including at least one of oxide, nitride, and oxynitride.

A bottom contact plug 104 may be formed in the lower interlayer dielectric layer 102. The bottom contact plug 104 may penetrate the lower interlayer dielectric layer 102 to connect to one terminal of a corresponding one of the select elements. The bottom contact plug 104 may include one or more of a doped semiconductor material (e.g., doped silicon), metal (e.g., tungsten, titanium, and/or tantalum), conductive metal nitride (e.g., titanium nitride, tantalum nitride, and/or tungsten nitride), and metal-semiconductor compound (e.g., metal silicide).

A bottom electrode layer BEL may be formed on the lower interlayer dielectric layer 102. The bottom electrode layer BEL may cover the bottom contact plug 104. The bottom electrode layer BEL may include conductive metal nitride such as titanium nitride and/or tantalum nitride. The bottom electrode layer BEL may include a material (e.g., ruthenium (Ru)) that assists crystal growth of magnetic layers which will be discussed below. The bottom electrode layer BEL may be formed by performing sputtering deposition, chemical vapor deposition, or atomic layer deposition.

A first magnetic layer 110 may be formed on the bottom electrode layer BEL (operation S10). The first magnetic layer 110 may be either a fixed layer having a unidirectionally fixed magnetization direction or a free layer having a variable magnetization direction. The first magnetic layer 110 may include at least one ferromagnetic element (e.g., cobalt, nickel, and iron). The first magnetic layer 110 may be formed by performing sputtering deposition, chemical vapor deposition, or physical vapor deposition.

Referring to FIGS. 6 and 8, a plurality of sputter guns (see 40 of FIGS. 1 and 2) may be provided above the first magnetic layer 110 (operation S20). For example, the substrate 100 on which the first magnetic layer 110 is formed may be provided in the process chamber 10 of the sputtering apparatus 500 discussed with reference to FIGS. 1 and 2. The substrate 100 may be loaded on the stage 22 of the substrate holder 20. The plurality of sputter guns 40 may be provided perpendicularly spaced apart from the first magnetic layer 110. Each of the plurality of sputter guns 40 may be provided spaced apart from the substrate 100, when viewed in a plan as in FIG. 1. The plurality of sputter guns 40 may include the first sputter gun 40A and the second sputter gun 40B. When viewed in a plan, the first sputter gun 40A may be spaced apart from the substrate 100 by the first distance d1, and the second sputter gun 40B may be spaced apart from the substrate 100 by the second distance d2. In one or more exemplary embodiments, as discussed with reference to FIGS. 1, 2, 4, and 5, the first and second sputter guns 40A and 40B may be provided asymmetrically about the reference normal line 100n perpendicular to the top surface 100U of the substrate 100, when viewed in a cross-section. In one or more other exemplary embodiments, as discussed with reference to FIGS. 1 and 3, the first and second sputter guns 40A and 40B may be provided symmetrically about the reference normal line 100n, when viewed in a cross-section.

The plurality of sputter guns 40 may include a plurality of targets 60, and the plurality of targets 60 may include the same material as each other. The plurality of targets 60 may include metal oxide, for example, magnesium (Mg) oxide, titanium (Ti) oxide, aluminum (Al) oxide, potassium (Ca) oxide, zirconium (Zr) oxide, magnesium-zinc (Mg—Zn) oxide, or magnesium-boron (Mg—B) oxide.

A sputtering deposition process P1 using the plurality of sputter guns 40 may be performed to form a non-magnetic layer 120 on the first magnetic layer 110 (operation S30). The non-magnetic layer 120 may be a tunnel barrier layer. The non-magnetic layer 120 may include the same material as those of the plurality of targets 60. The non-magnetic layer 120 may include metal oxide, for example, magnesium (Mg) oxide, titanium (Ti) oxide, aluminum (Al) oxide, potassium (Ca) oxide, zirconium (Zr) oxide, magnesium-zinc (Mg—Zn) oxide, or magnesium-boron (Mg—B) oxide. The sputtering deposition process P1 may be a radio-frequency sputtering process.

When the sputtering deposition process P1 is performed, each of the plurality of sputter guns 40 may be fixed on a position horizontally spaced apart from the substrate 100. Accordingly, even when a particle source is peeled off from outer surfaces of the plurality of sputter guns 40, the peeled-off particle source may be minimized or prevented from falling onto the substrate 100. As a result, contamination of the substrate 100 caused by the peeled-off particle source may be minimized or prevented.

As discussed with reference to FIGS. 1 to 5, the first sputter gun 40A and the second sputter gun 40B may be disposed such that the first projection area PA1 and the second projection area PA2 are horizontally spaced apart from the top surface 100U of the substrate 100. In this case, some of sputtering sources generated from the first target 60A and the second target 60B may diffuse toward the substrate 100 from the first projection area PA1 and the second projection area PA2, and the diffused sputtering sources may be deposited to form the non-magnetic layer 120 on the first magnetic layer 110.

When the first projection area PA1 and/or the second projection area PA2 overlap with the top surface 100U of the substrate 100, sputtering sources irregularly distributed in the first projection area PA1 and/or the second projection area PA2 may be deposited to form the non-magnetic layer 120 on the first magnetic layer 110. In this case, an irregular distribution of the sputtering sources may lead to an increase in dispersion of resistance RA in the non-magnetic layer 120. According to aspects of one or more exemplary embodiments, since the non-magnetic layer 120 is formed by the diffused sputtering sources, the non-magnetic layer 120 may be less affected by the irregular distribution of the sputtering sources in the first projection area PA1 and the second projection area PA2. Accordingly, the non-magnetic layer 120 may decrease in resistance dispersion, and thus a magnetic memory device may be improved in electrical characteristics.

Furthermore, according to aspects of one or more exemplary embodiments, the first sputter gun 40A may be inclined relative to the top surface 100U of the substrate 100 such that the projected plane PP1 of the first projection area PA1 is distant from the substrate 100. In this case, the irregular distribution of the sputtering sources in the first projection area PA1 may have less of an effect on characteristics of the non-magnetic layer 120. For example, the non-magnetic layer 120 may decrease in resistance dispersion. The second sputter gun 40B may be disposed such that the projection plane PP2 of the second projection area PA2 is closer to the substrate 100 than the projected plane PP1 of the first projection area PA1. As such, a deposition rate of the non-magnetic layer 120 may increase.

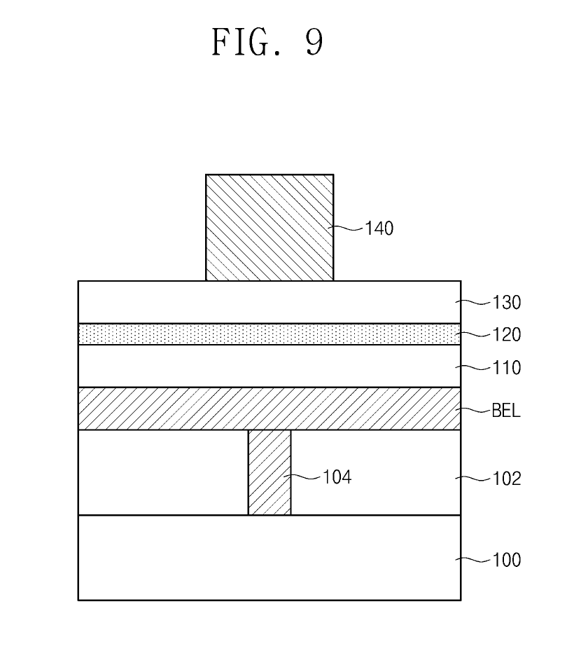

Referring to FIGS. 6 and 9, a second magnetic layer 130 may be formed on the non-magnetic layer 120 (operation S40). The second magnetic layer 130 may be either a fixed layer having a unidirectionally fixed magnetization direction or a free layer having a variable magnetization direction. One of the first magnetic layer 110 and the second magnetic layer 130 may correspond to a fixed layer having a unidirectionally fixed magnetization direction, and the other of the first magnetic layer 110 and the second magnetic layer 130 may correspond to a free layer having a magnetization direction that can be changed to be parallel or antiparallel to the fixed magnetization direction. The second magnetic layer 130 may include at least one ferromagnetic element (e.g., cobalt, nickel, and iron). The second magnetic layer 130 may be formed by performing sputtering deposition, chemical vapor deposition, or physical vapor deposition.

A conductive mask pattern 140 may be formed on the second magnetic layer 130. The conductive mask pattern 140 may include one or more of tungsten, titanium, tantalum, aluminum, and metal nitride (e.g., titanium nitride and tantalum nitride). The conductive mask pattern 140 may define a planar shape of a magnetic tunnel junction pattern, which will be discussed below.

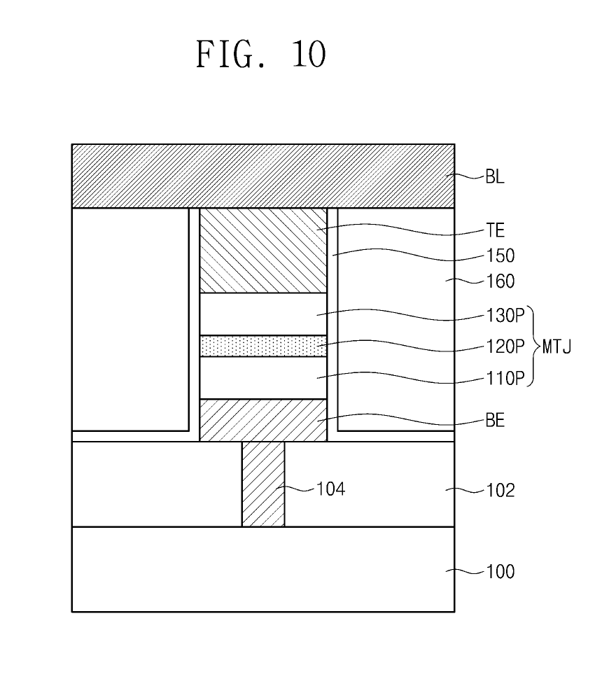

Referring to FIGS. 6 and 10, the second magnetic layer 130, the non-magnetic layer 120, and the first magnetic layer 110 may be sequentially patterned to form a magnetic tunnel junction pattern MTJ (operation S50). For example, the conductive mask pattern 140 may be used as an etching mask to sequentially etch the second magnetic layer 130, the non-magnetic layer 120, the first magnetic layer 110, and the bottom electrode layer BEL. Therefore, a bottom electrode BE, a first magnetic pattern 110P, a non-magnetic pattern 120P, and a second magnetic pattern 130P may be formed to be sequentially stacked on the lower interlayer dielectric layer 102. The magnetic tunnel junction pattern MTJ may include the first magnetic pattern 110P, the non-magnetic pattern 120P, and the second magnetic pattern 130P that are sequentially stacked on the bottom electrode BE. The non-magnetic pattern 120P may be called a tunnel barrier pattern. The conductive mask pattern 140 may serve as a top electrode TE. The bottom electrode BE may be in contact with the bottom contact plug 104. The magnetic tunnel junction pattern MTJ may be electrically connected through the bottom electrode BE to the bottom contact plug 104.

In one or more exemplary embodiments, as illustrated in FIG. 11, the first magnetic pattern 110P and the second magnetic pattern 130P may have respective magnetization directions 110m and 130m substantially parallel to an interface between the non-magnetic pattern 120P and the second magnetic pattern 130P. FIG. 11 shows an example where the first magnetic pattern 110P is a fixed layer and the second magnetic pattern 130P is a free layer, though it is understood that one or more other exemplary embodiments are not limited thereto. For example, according to another exemplary embodiment, the first magnetic pattern 110P may be a free layer and the second magnetic pattern 130P may be a fixed layer. Each of the first magnetic pattern 110P and the second magnetic pattern 130P having the parallel magnetization directions 110m and 130m may include a ferromagnetic material. The first magnetic pattern 110P may further include an anti-ferromagnetic material for fixing a magnetization direction of the ferromagnetic material in the first magnetic pattern 110P.

In one or more other exemplary embodiments, as illustrated in FIG. 12, the first magnetic pattern 110P and the second magnetic pattern 130P may have respective magnetization directions 110m and 130m substantially perpendicular to an interface between the non-magnetic pattern 120P and the second magnetic pattern 130P. FIG. 12 shows an example where the first magnetic pattern 110P is a fixed layer and the second magnetic pattern 130P is a free layer, though it is understood that one or more other exemplary embodiments are not limited thereto. For example, according to another exemplary embodiment, the first magnetic pattern 110P may be a free layer and the second magnetic pattern 130P may be a fixed layer. Each of the first magnetic pattern 110P and the second magnetic pattern 130P having the perpendicular magnetization directions 110m and 130m may include one or more of a perpendicular magnetic material (e.g., CoFeTb, CoFeGd, CoFeDy), a perpendicular magnetic material having an L₁₀ structure, CoPt of a hexagonal close packed lattice structure, and a perpendicular magnetization structure. The perpendicular magnetic material having the L₁₀ structure may include one or more of FePt of the L₁₀ structure, FePd of the L₁₀ structure, CoPd of the L₁₀ structure, and CoPt of the L₁₀ structure. The perpendicular magnetization structure may include magnetic layers and non-magnetic layers that are alternately and repeatedly stacked. For example, the perpendicular magnetization structure may include one or more of (Co/Pt)n, (CoFe/Pt)n, (CoFe/Pd)n, (Co/Pd)n, (Co/Ni)n, (CoNi/Pt)n, (CoCr/Pt)n, and (CoCr/Pd)n (where n is the stack number).

Referring back to FIGS. 6 and 10, a protection layer 150 may be formed on the lower interlayer dielectric layer 102 to conformally cover side surfaces of the bottom electrode BE, the magnetic tunnel junction pattern MTJ, and the top electrode TE. The protection layer 150 may extend onto a top surface of the lower interlayer dielectric layer 102. The protection layer 150 may include, for example, a silicon nitride layer. An upper interlayer dielectric layer 160 may be formed on the lower interlayer dielectric layer 102 to cover the bottom electrode BE, the magnetic tunnel junction pattern MTJ, the top electrode TE, and the protection layer 150. The upper interlayer dielectric layer 160 may be a single layer or a multiple layer. For example, the upper interlayer dielectric layer 160 may include an oxide layer (e.g., a silicon oxide layer), a nitride layer (e.g., a silicon nitride layer), or an oxynitride layer (e.g., a silicon oxynitride layer).

A bit line BL may be formed on the upper interlayer dielectric layer 160. The bit line BL may extend in one direction, and may be electrically connected to a plurality of the magnetic tunnel junction patterns MTJ arranged along the one direction. The magnetic tunnel junction pattern MTJ may be electrically connected through the top electrode TE to the bit line BL.

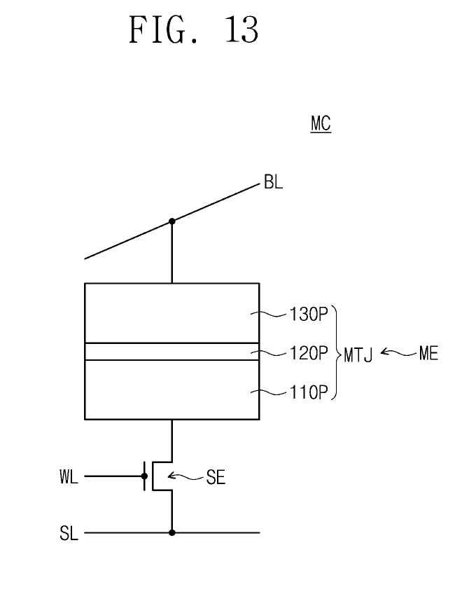

FIG. 13 is a circuit diagram illustrating a unit memory cell of a magnetic memory device according to an exemplary embodiment.

Referring to FIG. 13, a unit memory cells MC may include a magnetic memory element ME and a select element SE. The select element SE and the magnetic memory element ME may be electrically connected in series. The magnetic memory element ME may be connected between the select element SE and a bit line BL. The select element SE may be connected between the magnetic memory element ME and a source line SL, and controlled by a word line WL.

The magnetic memory element ME may include a magnetic tunnel junction pattern MTJ. The magnetic tunnel junction pattern MTJ may include a tunnel barrier pattern 120P, a first magnetic pattern 110P, and a second magnetic pattern 130P that is spaced apart from the first magnetic pattern 110P across the tunnel barrier pattern 120P. One of the first magnetic pattern 110P and the second magnetic pattern 130P may be a fixed layer having a magnetization direction that is fixed regardless of an external magnetic field under a normal use environment. The other of the first magnetic pattern 110P and the second magnetic pattern 130P may be a free layer having a magnetization direction that is freely changed by an external magnetic field.

The magnetic tunnel junction pattern MTJ may have an electrical resistance that is much greater when magnetization directions of the fixed and free layers are antiparallel to each other than when magnetization directions of the fixed and free layers are parallel to each other. For example, the electrical resistance of the magnetic tunnel junction pattern MTJ may be controlled by changing the magnetization direction of the free layer. Accordingly, the magnetic memory element ME may store data in the unit memory cell MC using a difference in electrical resistance depending on the magnetization direction.

According to aspects of one or more exemplary embodiments, the sputtering apparatus 500 may include the plurality of sputter guns 40 provided in the process chamber 10. Each of the plurality of sputter guns 40 may be disposed spaced apart from the substrate 100, when viewed in a plan as in FIG. 1. Accordingly, contamination of the substrate 100 caused by particle sources peeled off from outer surfaces of the plurality of sputter guns 40 may be minimized or prevented.

The plurality of sputter guns 40 may include the first sputter gun 40A and the second sputter gun 40B. The first sputter gun 40A may be disposed such that the first projection area PA1 is horizontally spaced apart from the top surface 100U of the substrate 100, and also may be inclined relative to the top surface 100U of the substrate 100 such that the projected plane PP1 of the first projection area PA1 is distant from the substrate 100. The second sputter gun 40B may be disposed such that the second projection area PA2 is horizontally spaced apart from the top surface 100U of the substrate 100, and such that the projected plane PP2 of the second projection area PA2 is closer to the substrate 100 than the first projected plane PP1 of the first projection area PA1. Accordingly, deterioration of characteristics of the thin layer (e.g., dispersion in resistance of the non-magnetic layer 120) caused by the irregular distribution of the sputtering sources in the first projection area PA1 and the second projection area PA2 may be minimized or prevented, and a reduction in deposition rate of the thin layer may be compensated.

According to aspects of one or more exemplary embodiments, the sputtering apparatus may be provided to minimize contamination of the substrate loaded therein and to reduce deterioration in characteristics of thin films. Moreover, when the sputtering apparatus is used to deposit the tunnel barrier layer of the magnetic tunnel junction pattern, the tunnel barrier layer may decrease in resistance dispersion. Accordingly, it may be possible to enhance electrical characteristics of a magnetic memory device including the magnetic tunnel junction pattern.

The aforementioned description provides exemplary embodiments for explaining inventive concepts. Therefore, inventive concepts are not limited to exemplary embodiments described above, and it will be understood by one of ordinary skill in the art that variations in form and detail may be made therein without departing from the spirit and features of inventive concepts.

1. A sputtering apparatus, comprising:
a process chamber;
a stage in the process chamber and configured to load a substrate thereon; and
a first sputter gun above the substrate in the process chamber,
wherein the first sputter gun is horizontally spaced apart from the substrate,
wherein the first sputter gun comprises a first target including a first end and a second end, the first end of the first target being horizontally closer to the substrate than the second end of the first target, and
wherein a first surface of the first target is inclined relative to a top surface of the substrate, and a height of the second end of the first target relative to the top surface of the substrate is greater than a height of the first end of the first target relative to the top surface of the substrate.

2. The sputtering apparatus of claim 1, further comprising:
a second sputter gun above the substrate in the process chamber and horizontally spaced apart from the first sputter gun,
wherein the second sputter gun is horizontally spaced apart from the substrate,
wherein the second sputter gun comprises a second target, and
wherein a first surface of the second target is parallel to the top surface of the substrate.

3. The sputtering apparatus of claim 2, wherein the first target and the second target comprise a same material as each other.

4. The sputtering apparatus of claim 1, further comprising:
a second sputter gun above the substrate in the process chamber and horizontally spaced apart from the first sputter gun,
wherein the second sputter gun is horizontally spaced apart from the substrate,
wherein the second sputter gun comprises a second target including a first end and a second end, the first end of the second target being horizontally closer to the substrate than the second end of the second target, and
wherein a first surface of the second target is inclined relative to the top surface of the substrate, and a height of the first end of the second target relative to the top surface of the substrate is greater than a height of the second end of the second target relative to the top surface of the substrate.

5. The sputtering apparatus of claim 4, wherein the first target and the second target comprise a same material as each other.

6. The sputtering apparatus of claim 1, wherein the first sputter gun further comprises:
a first plate on a second surface of the first target, opposite to the first surface of the first target, and configured to supply power to the first target; and
a first shield surrounding a periphery of the first target and exposing the first surface of the first target,
wherein the first shield is horizontally spaced apart from the substrate.

7. The sputtering apparatus of claim 1, wherein:
the first sputter gun further comprises a first plate on a second surface of the first target, opposite to the first surface of the first target, and configured to supply power to the first target; and
an angle is formed between a first normal line perpendicular to the first surface of the first target and a reference normal line perpendicular to and extending vertically from the top surface of the substrate, the angle ranging from 1° to 50°.

8. The sputtering apparatus of claim 1, wherein:
the first sputter gun further comprises a first plate on a second surface of the first target, opposite to the first surface of the first target, and configured to supply power to the first target; and
an angle is formed between a first normal line perpendicular to the first surface of the first target and a reference normal line perpendicular to and extending vertically from the top surface of the substrate, the angle ranging from 1° to 5°.

9. The sputtering apparatus of claim 1, further comprising:
a second sputter gun above the substrate in the process chamber and horizontally spaced apart from the first sputter gun,
wherein the second sputter gun is horizontally spaced apart from the substrate,
wherein the second sputter gun comprises a second target including a first end and a second end, the first end of the second target being horizontally closer to the substrate than the second end of the second target, and
wherein a first surface of the second target is inclined relative to the top surface of the substrate, and a height of the second end of the second target relative to the top surface of the substrate is greater than a height of the first end of the second target relative to the top surface of the substrate.

10. The sputtering apparatus of claim 9, wherein the first sputter gun and the second sputter gun are provided symmetrically about a reference normal line perpendicular to the top surface of the substrate and extending vertically from the top surface of the substrate.

11. A sputtering apparatus, comprising:
a process chamber;
a stage in the process chamber and configured to load a substrate thereon;
a first sputter gun above the substrate in the process chamber, the first sputter gun comprising a first target; and
a second sputter gun above the substrate in the process chamber, the second sputter gun comprising a second target,
wherein the first sputter gun and the second sputter gun are horizontally spaced apart from the substrate,
wherein the first target comprises a first end and a second end, the first end of the first target being horizontally closer to the substrate than the second end of the first target, and
wherein a first surface of the first target is inclined relative to a top surface of the substrate, and a height of the second end of the first target relative to the top surface of the substrate is greater than a height of the first end of the first target relative to the top surface of the substrate.

12. The sputtering apparatus of claim 11, wherein the first target and the second target comprise a same material as each other.

13. (canceled)

14. The sputtering apparatus of claim 11, wherein a first surface of the second target is parallel to the top surface of the substrate.

15. The sputtering apparatus of claim 11, wherein:
the second target comprises a first end and a second end, the first end of the second target being horizontally closer to the substrate than the second end of the second target; and
a first surface of the second target is inclined relative to the top surface of the substrate, and a height of the first end of the second target relative to the top surface of the substrate is greater than a height of the second end of the second target relative to the top surface of the substrate.

16. The sputtering apparatus of claim 11, wherein:
the second target comprises a first end and a second end, the first end of the second target being horizontally closer to the substrate than the second end of the second target; and
a first surface of the second target is inclined relative to the top surface of the substrate, and a height of the second end of the second target relative to the top surface of the substrate is greater than a height of the first end of the second target relative to the top surface of the substrate.

17. The sputtering apparatus of claim 11, wherein the first sputter gun and the second sputter gun are provided asymmetrically about a reference normal line perpendicular to and extending vertically from the top surface of the substrate.

18. The sputtering apparatus of claim 11, wherein the first sputter gun and the second sputter gun are provided symmetrically about a reference normal line perpendicular to and extending vertically from the top surface of the substrate.

19. The sputtering apparatus of claim 11, wherein:
the first sputter gun further comprises:
a first plate on a second surface of the first target, opposite to the first surface of the first target, and configured to supply power to the first target, and
a first shield surrounding a periphery of the first target;
the second sputter gun further comprises:
a second plate on a second surface of the second target, opposite to a first surface of the second target, and configured to supply power to the second target, and
a second shield surrounding a periphery of the second target; and
the first shield and the second shield are horizontally spaced apart from the substrate.

20. The sputtering apparatus of claim 11, wherein:
a projection area of the first sputter gun is horizontally spaced apart from the top surface of the substrate, the projection area being an area formed when the first surface of the first target extends along a normal line onto a plane including the top surface of the substrate, the normal line being perpendicular to the first surface of the first target; and
the first sputter gun is inclined relative to the top surface of the substrate such that a projected plane of the projection area is spaced apart from the substrate, the projected plane being a plane formed when the first surface of the first target is projected along the normal line onto the plane.

21-25. (canceled)

26. A sputtering apparatus, comprising:
a process chamber;
a stage in the process chamber and configured to load a substrate thereon; and
a first sputter gun above the substrate in the process chamber and comprising a first target,
wherein the first sputter gun is horizontally spaced apart from the substrate, and
wherein a first projection area of the first sputter gun is horizontally spaced apart from a top surface of the substrate, the first projection area being an area formed when a first surface of the first target extends along a first normal line onto a plane including the top surface of the substrate, the first normal line being perpendicular to the first surface of the first target.

27-29. (canceled)
